(19) United States
(12) Patent Application Publication
(10) Pub. No.: US 2026/0293271 A1
(43) Pub. Date: Sep. 24, 2026

(54) CONTINUED MIXED ROW STANDARD CELL DESIGN

(71) Applicant: International Business Machines Corporation, Armonk, NY (US)

(72) Inventors: Ryan Kosciolek, Albany, NY (US); Albert Manhee Chu, Nashua, NH (US); Jason J. Stuffle, Burlington, VT (US); Brent Alan Anderson, Jericho, VT (US)

(21) Appl. No.: 19/085,488

(22) Filed: Mar. 20, 2025

(51) Int. Cl. H10D 80/20; H10W 20/41

(52) U.S. Cl. CPC H10D 80/251; H10W 20/427

(57) ABSTRACT

The present disclosure provides a semiconductor device comprising a first standard cell column comprising three first N and P transistor pairs and a second standard cell column horizontally adjacent to the first standard cell column comprising two second N and P transistor pairs, wherein a top edge and a bottom edge of the first standard cell column is horizontally aligned with a respective top edge and a respective bottom edge of the second standard cell column.

### FIELD OF INVENTION

The present disclosure relates to integrated circuit design, and more particularly to a continuous mixed row (CMR) standard cell design with shared power rails.

### BACKGROUND

Integrated circuit design continues to evolve as semiconductor manufacturing processes advance. As transistor sizes shrink and circuit densities increase, designers face challenges in balancing performance, power consumption, and area efficiency. Standard cell libraries play a crucial role in modern integrated circuit design, providing pre-designed logic gates and other basic building blocks that can be combined to create complex digital circuits.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a semiconductor structure is provided. The semiconductor structure includes a first standard cell column comprising three first N and P transistor pairs and a second standard cell column horizontally adjacent to the first standard cell column comprising two second N and P transistor pairs, wherein a top edge and a bottom edge of the first standard cell column is horizontally aligned with a respective top edge and a respective bottom edge of the second standard cell column.

According to another aspect of the present disclosure, a semiconductor structure is provided. The semiconductor structure includes a continuous mixed row of N and P transistor pairs that include a first N and P transistor pair having a first height and a second N and P transistor pair having a second height, wherein the second height is one and one-half times a height of the first height.

According to other aspects of the present disclosure, a semiconductor structure is provided. The semiconductor structure includes a first standard cell column and a second standard cell column, wherein the first standard cell column and the second standard cell column have a same height, and wherein the first standard cell column includes three standard cells while the second standard cell column includes two standard cells.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates a top view of a semiconductor structure 100 showing an arrangement of standard cells and power rails, according to an embodiment.

FIG. 2 illustrates a top view of a semiconductor structure 200 showing an arrangement of standard cells and power rails, according to an embodiment.

FIG. 3 illustrates a top view of a semiconductor structure 300, according to an embodiment.

FIG. 4 illustrates cross-sectional views of the semiconductor structure 300 taken along dashed line A and dashed line B of FIG. 3, according to an embodiment.

FIG. 5 illustrates a top view of a semiconductor structure 400, according to an embodiment.

FIG. 6 illustrates cross-sectional views of the semiconductor structure 400 taken along dashed line A and dashed line B of FIG. 5, according to an embodiment.

FIG. 7 illustrates a top view of a semiconductor structure 500, according to an embodiment.

FIG. 8 illustrates cross-sectional views of the semiconductor structure 500 taken along dashed line A and dashed line B of FIG. 7, according to an embodiment.

FIG. 9 illustrates a top view of a semiconductor structure 600, according to an embodiment.

FIG. 10 illustrates cross-sectional views of the semiconductor structure 600 taken along dashed line A and dashed line B of FIG. 9, according to an embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, regions or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sublithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The following description sets forth exemplary aspects of the present disclosure. It should be recognized, however, that such description is not intended as a limitation on the scope of the present disclosure. Rather, the description also encompasses combinations and modifications to those exemplary aspects described herein.

As previously noted, integrated circuit design continues to evolve as semiconductor manufacturing processes advance. As transistor sizes shrink and circuit densities increase, designers face challenges in balancing performance, power consumption, and area efficiency. Standard cell libraries play a crucial role in modern integrated circuit design, providing pre-designed logic gates and other basic building blocks that can be combined to create complex digital circuits.

Traditionally, standard cell libraries have consisted of cells arranged in a grid-like structure with uniform heights, allowing for straightforward placement and routing. This approach, however, can lead to inefficiencies in area utilization and power distribution, particularly as circuit designs become more complex and diverse in their requirements.

Recent developments in integrated circuit design have explored the use of mixed-height standard cell libraries, where cells of different heights can be combined within the same circuit design or layout. This approach offers potential benefits in terms of flexibility and optimization, allowing designers to choose cell size that better matches the specific performance and area requirements of different parts of a circuit.

Implementing designs with mixed-height cells, however, presents several challenges. Power distribution becomes more complex when cells of different heights are placed adjacent to each other, as power rails may not align perfectly. Additionally, the placement and routing tools used in integrated circuit design must be adapted to handle the increased complexity of working with cells of varying heights.

Furthermore, as transistor technologies continue to advance, new design approaches are needed to take full advantage of their capabilities. For example, the transition from planar transistors to FinFETs and gate-all-around structures introduces new considerations in terms of layout and power distribution.

Designers are constantly seeking ways to improve the efficiency and performance of integrated circuits while maintaining manufacturability and reliability. As such, there is ongoing research and development in the field of standard cell design and layout methodologies to address these challenges and enable the creation of more advanced and efficient integrated circuits.

The present disclosure relates to integrated circuit design, particularly to a continuous mixed row standard cell design with shared power rails. This design approach may provide advantages in terms of area efficiency and wire length reduction in integrated circuits.

In the field of integrated circuit design, continuous mixed row standard cell design with shared power rails represents an innovative approach to addressing the challenges of modern semiconductor manufacturing. This design methodology aims to optimize area efficiency, power distribution, and overall circuit performance by leveraging a unique arrangement of standard cells and power rail structures.

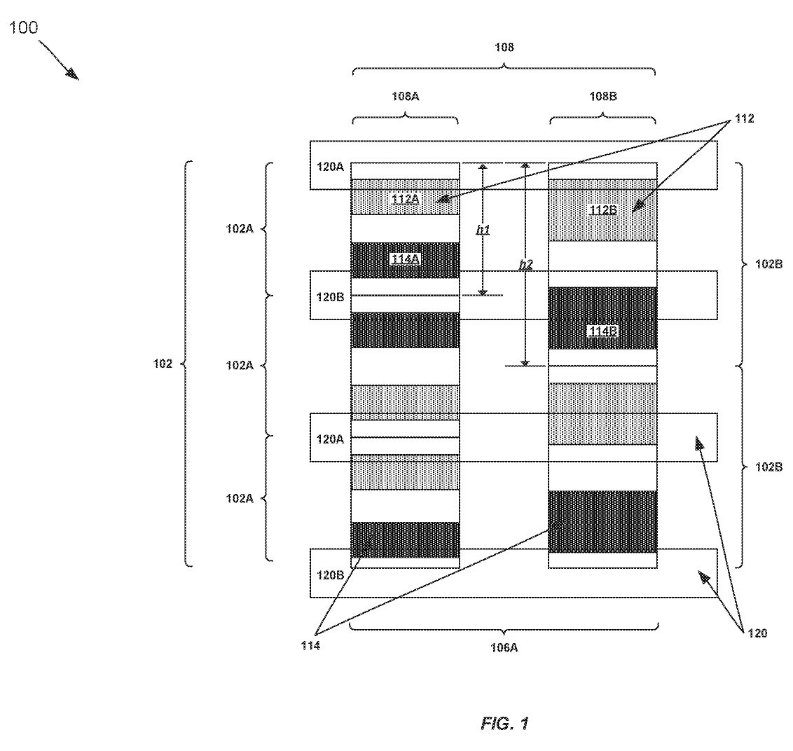

Exemplary embodiments of continuous mixed row standard cell design with shared power rails are described in detail below by referring to the accompanying drawings in FIG. 1-10. Those skilled in the art will readily appreciate that the detailed description given herein with respect to these figures is for explanatory purposes as the invention extends beyond these limited embodiments.

FIG. 1 illustrates a top view of a semiconductor structure 100 showing an arrangement of standard cells and power rails, according to an embodiment.

As illustrated, the semiconductor structure 100 includes a first cell group 106A, power rails 120A, and power rails 120B (the power rails 120A and the power rails 120B may be collectively referred to as “the power rails 120”).

In embodiments, the cell group 106A includes a first column 108A and a second column 108B (collectively referred to as “the columns 108,” “standard cell columns”). As illustrated, the column 108A includes three of the cells 102A and the column 108B includes two of the cells 102B (all of the cells 102A and the cells 102B may be collectively referred to as “the cells 102”).

As illustrated, the power rails 120 extend across the cell group 106A perpendicular to the columns 108. In embodiments, the power (e.g., voltage) supplied by the power rails 120A may be different than the power supplied by the power rails 120B.

As shown, the arrangement of the cells 102 and the power rails 120 form a grid of columns and rows with the cells 102 extending vertically in columns along the columns 108 and horizontally in rows along the power rails 120. That is, the columns of grid may be roughly defined by the columns 108 while the rows of the grid may be roughly defined as an area between the power rails 120A and the power rails 120B. Because the row of the cells 102 includes both the cells 102A that are shorter and the cells 102B that are taller, the row is referred to as a continuous mixed row (CMR). That is, the cells 102A with height h1 are in a same row as the cells 102B with height h2 even though h2 is taller than h1. Thus, the cells 102 are mixed within the row (and potentially along the columns). And, as noted above, while continuous mixed rows have their benefits, they also present a challenge of adequately and efficiently connecting power rails 120 to all of the cells 102 within a continuous mixed row.

The column 108A includes three of the cells 102A each having a first cell height (h1) and the column 108B includes two of the cells 102B each having a second cell height (h2). In embodiments, and as illustrated, the h2 is larger than h1, and therefore the cells 102B are larger than the cells 102A. For example, here, h2 and the cells 102B are each roughly one-and-a-half times (1.5x) a height of h1 and each of the cells 102A.

This choice in sizing the cells 102 is important for several reasons. Advantageously, by sizing the cells 102A to the cells 102B in a 1:1.5 ratio, the invention allows for the cells 102A to be stacked to the cells 102B in a 3:2 (and 6:4, 9:6, etc.) ratio, resulting in the column 108A and the column 108B having a same height when placed adjacently (as shown). That is, a top edge/border of the column 108A horizontally aligns with a top edge/border of the column 108B, and a bottom edge/border of the column 108A horizontally aligns with a bottom edge/border of the column 108B.

This choice in sizing and layout of the cell group 106A (i.e., 3:2 ratio) alleviates much of the difficulty in supplying power to all the mixed sizes of the cells 102 in a continuous mixed row noted above because it horizontally aligns many of the top and bottom edges/ends of the cells 102 with two of the power rails 120. Further, the cells 102 in which the power rails 120 do not align with a vertical edge/end of are still powered by one of the power rails 120 at a non-edge of the cells 102. Therefore, as illustrated by FIG. 1, the layout not only effectively aligns all the cells 102 with two of the power rails 120, but further aligns a majority (e.g., 8/10) of the top and bottom edges/ends of the cells 102 with one of the power rails 120. Put another way, only two of the ten vertical edges/ends of the cells 102 do no align with one of the power rails 120. Therefore, even when implementing three of the cells 102A of height h1 and two of the cells 102B of height h2, the layout aligns a majority of the top and bottom edges/ends of the cells 102 with one of the power rails 120. As a result, the layout lends itself to the use of standardized components and the cell group 106A can be adjacently scaled in all directions. While only two columns and three rows are illustrated by FIG. 1, embodiments of the present invention explicitly contemplate the semiconductor structure 100 including any number of columns, rows, and cells.

As further illustrated by FIG. 1, each of the cells 102 include source/drain regions 112A and source/drain regions 112B (collectively referred to as “the source/drain regions 112”) as well as source/drain regions 114A and source/drain regions 114B (collectively referred to as “the source/drain regions 114”) that represent P-type and N-type regions of the cells 102. For example, the source/drain regions 112 may represent the P-type regions while the source/drain regions 114 may represent the N-type regions. As illustrated, the column 108A comprises three vertically aligned cells 102A that each include an N and P transistor pair, while the column 108B comprises two vertically aligned cells 102B that each include an N and P transistor pair.

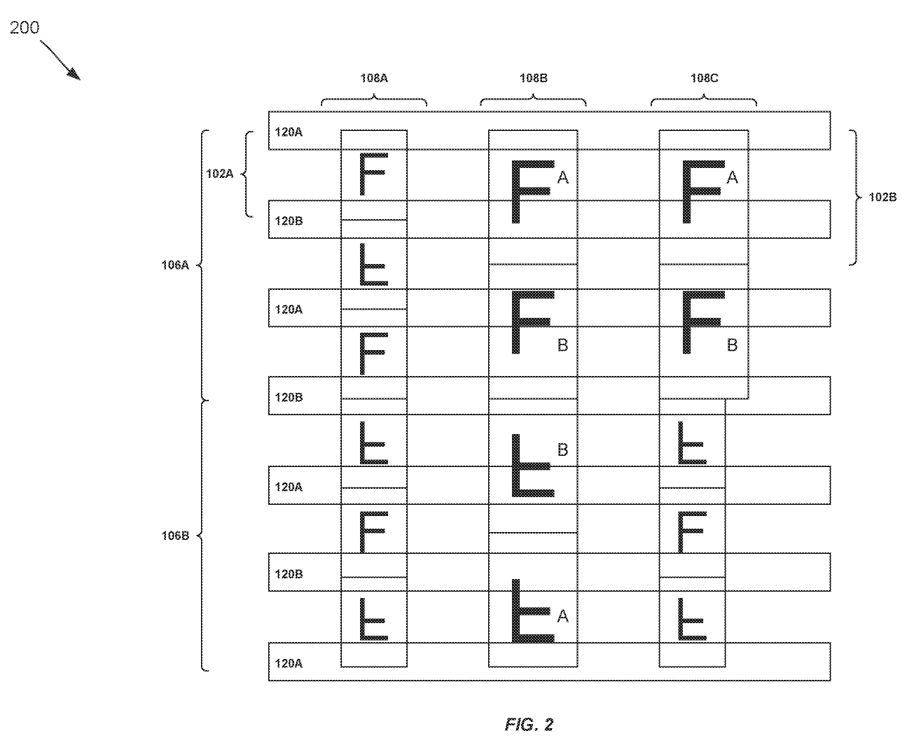

In embodiments, the semiconductor structure 100 is configured such that a same P-type or N-type transistor region of the cells 102 align with a same power rail 120. For example, as illustrated, the source/drain regions 112 of the cells 102 are at least partially aligned with the power rails 120A. Conversely, the source/drain regions 114 of the cells 102 are at least partially aligned with the power rail 120B. This feature is accomplished by vertically flipping the cell 102A in the middle of the column 108A, which will be further illustrated by FIG. 2.

Importantly, and as noted above, each of the cells 102 within the cell group 106A is at least partially aligned with both the power rails 120A and the power rail 120B despite the cells 102B having roughly 1.5 times the vertical size of the cells 102A. This designed contact with two of the power rails 120, combined with aligning the P-type and N-type (source/drain regions 112 or source/drain regions 114) to a same version of the power rails 120A or the power rails 120B, allows for a voltage difference between the power rails 120A and the power rails 120B across the cells 102.

The cell group 106A of FIG. 1 illustrates how the cells 102 are arranged in a grid roughly between the power rails 120A and the power rails 120B, allowing for efficient use of space while maintaining proper voltage distribution throughout the device. In particular, the cell group 106A maintains consistent spacing and power rail alignment of the N- and P-type regions across the mixed-size versions of the cells 102.

As further illustrated, by sizing a height of the cells 102B at one and one-half times (1.5x) that of the cells 102A, three of the cells 102A can be stacked for every two of the cells 102B (i.e., 3:2 ratio), thereby matching the heights of the column 108A and the column 108B. It will be appreciated that any number of the cell group 106A may be arranged adjacently, or the ratio can be increased to, for example, 6:4, 9:6, and so forth. In addition, the ratio of the cells 102A (h1) to the cells 102B (h2) may vary, for example, in some cases, the ratios (h1:h2) may include 1:1, 1:1.25, 1:1.75, 1:2, 1:3, 1:4, etc. The specific aspect ratio chosen may depend on the design requirements and constraints of the semiconductor structure 100.

While the drawings illustrate a particular overlap between the power rails 120 and the cells 102 (and the source/drain regions 112 and source/drain regions 114 thereof), in other embodiments, the invention may implement a different overlap or underlap/offset. Overall, alignment of the components herein may vary so long as they maintain electrical conductivity where necessary.

FIG. 2 illustrates a top view of a semiconductor structure 200 showing an arrangement of standard cells and power rails, according to an embodiment.

The layout illustrated by FIG. 2 is an expanded version of that illustrated by FIG. 1 and includes a second cell group 106B and a third column 108C. In addition, here, the cells 102 are denoted by an "F" for FET.

The column 108A includes six of the cells 102A vertically spread across the cell group 106A and the cell group 106B. Notably, every other of the cells 102A is vertically flipped to maintain proper top and bottom edge/end alignment with the power rails 120 having a desirable power output (e.g., aligning a N-type or P-type region).

The column 108B includes four of the cells 102B, with the cells 102B in the cell group 106A in an upright (upside-up) orientation and the cells 102B in the cell group 106B in an upside-down orientation. As previously noted, flipping a cell 102, for example the cells 102B in the cell group 106B, allow for aligning a desirable edge/end of the cell 102 to an appropriate power rail 120 (i.e., the power rail 120A or the power rail 120B).

Column 108C includes two of the cells 102B in the cell group 106A and three of the cells 102A in the cell group 106B with every other vertically flipped.

FIG. 2 further illustrates specifically where in which the cells 102 align with the power rails 120. In other words, the power rails 120 may align with either a top/bottom edge of the cells 102 or misalign with/offset from both a top/bottom edge of the cells 102. For example, in the column 108A, the power rails 120A and the power rails 120B are aligned with top/bottom edges of the cells 102A. That is, the cells 102A in the column 108A terminate at a top or bottom edge/end within the footprint of the power rails 120. By contrast, only one of the top or bottom edges of the cells 102B align with the power rails 120. For example, only a top edge/end of the cells 102B annotated with a superscript "A" align with the power rails 120A while the bottom edges/ends are misaligned with the power rails 120B. Instead, the bottom edge/end of the cells 102B annotated with a superscript "A" is offset from the power rails 120B. Similarly, a top edge/end of the cells 102B annotated with a superscript "B" align with the power rails 120B while the bottom edges/ends are misaligned with the power rails 120A. Nonetheless, and advantageously, each of the cells 102 illustrated align with both the power rails 120A and the power rails 120B, whether at an edge or a non-edge.

The arrangement shown in FIG. 2 demonstrates various arrangements of the cells 102 contemplated by the invention whilst maintaining at least partial alignment with both the power rails 120A and the power rails 120B. While only the cell group 106A and the cell group 106B are illustrated for brevity, additional cell groupings based on the layouts illustrated by FIG. 2 are contemplated in a wide variety of arrangements.

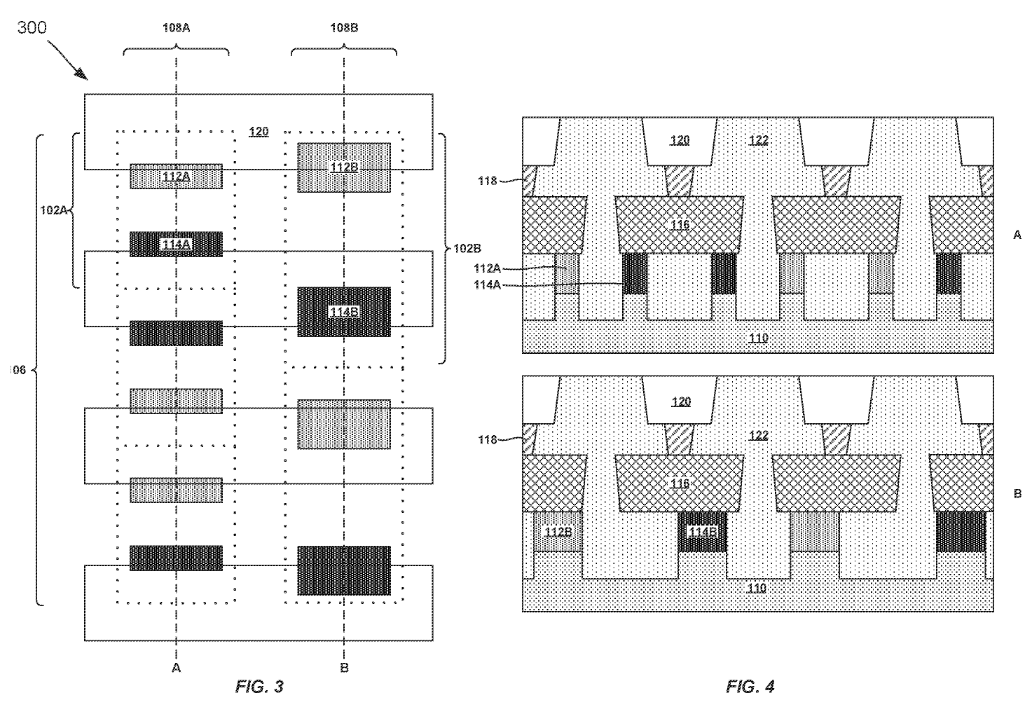

FIG. 3 illustrates a top view of a semiconductor structure 300 while FIG. 4 illustrates cross-sectional views taken along dashed line A and dashed line B of FIG. 3, according to an embodiment.

The semiconductor structure 300 illustrates a semiconductor device having a frontside power rail.

The semiconductor structure 300 of FIG. 3 is similar to the semiconductor structure 100 of FIG. 1 in that both illustrate the cell group 106A having three of the cells 102A arranged vertically in the column 108A (delineated by a dotted line) side by side with two of the cells 102B arranged vertically in the column 108B (also delineated by a dotted line), forming the 3:2 ratio of the cells 102A to the cells 102B.

The semiconductor structure 300 includes a substrate 110. The substrate 110 may serve as a foundation for the device structure. In embodiments, the substrate 110 may be any bulk substrate made from any known semiconductor materials such as, for example, silicon, germanium, silicon-germanium alloy, and compound (e.g. III-V and II-VI) semiconductor materials. As illustrated, portions of the substrate 110 may be recessed, creating portions of the substrate 110 that are proud relative to the those recessed. The portions of the substrate 110 may be recessed by, for example, an etching process.

The semiconductor structure 300 further includes a dielectric region 122 formed on top of the substrate 110. The dielectric region 122 may be composed of any suitable dielectric material such as, for example, oxides such as silicon oxide (SiOx), nitrides such as silicon nitride (SixNy), and/or low-κ materials such as SiCOH or SiBCN. In another embodiment, the dielectric region is composed of silicon dioxide, undoped silicate glass (USG), fluorosilicate glass (FSG), borophosphosilicate glass (BPSG), a spin-on low k dielectric layer, a chemical vapor deposition (CVD) low k dielectric layer or any combination thereof. As used here, the dielectric region 122 provides electrical isolation between adjacent components.

The semiconductor structure 300 further includes the source/drain regions 112 and the source/drain regions 114. More specifically, the source/drain regions 112A and the source/drain regions 114A are included within the cells 102A while the source/drain regions 112B and the source/drain regions 114B are included within the cells 102B. The source/drain regions 112 and the source/drain regions 114 may each correspond to a P-type or N-type transistor region of the cells 102. For example, the source/drain regions 112 correspond to a P-type portion of the cells 102 while the source/drain regions 114 correspond to an N-type portion of the cells 102, or vice versa.

As illustrated, the source/drain regions 112 and the source/drain regions 114 may be formed on top of the proud, or non-recessed, portions of the substrate 110. The source/drain regions 112 and the source/drain regions 114 may be a doped semiconductor. The source/drain regions 112 and the source/drain regions 114 may be formed using techniques such as ion implantation and/or epitaxial growth. For example, the dielectric region 122 may be recessed down to the substrate 110 using an etching process, after which the source/drain region 112 and/or the source/drain regions 114 is formed by filling the recess using epitaxial growth.

Similar to FIG. 1, the source/drain regions 112B and the source/drain regions 114B are larger in size than the source/drain regions 112A and the source/drain regions 112B as a result of the cells 102B being roughly one and one-half times (1.5x) larger in vertical size than the cells 102A. This increased size allows for flexibility and variety in the cells 102 selected for the cell group 106A.

The semiconductor structure 300 further includes contacts 116. As illustrated, each of the contacts 116 make at least partial contact with at least one of the source/drain regions 112 and the source/drain regions 114. For example, in cross section A of FIG. 4, the contact 116 contacts two of the source/drain regions 112A and the source/drain regions 114A, while in cross section B of FIG. 4, the contact 116 contacts only one of the source/drain regions 112B or the source/drain regions 114B.

The contacts 116 may be made of tungsten, titanium, copper, ruthenium, palladium, platinum, cobalt, nickel, ruthenium oxide, aluminum, tantalum, hafnium zirconium, a metal carbide, conductive metal oxide, or carbon nano tube, and formed using known deposition techniques. For example, the dielectric region 122 may be recessed down to and exposing the source/drain regions 112 and the source/drain regions 114 using, for example, an etching process, then the recesses are filled with tungsten using a known deposition technique.

The semiconductor structure 100 further includes vias 118. The vias 118 may connect metal layers within the cells of the device, facilitating vertical electrical connections between different levels of the structure. The vias may be formed of a metallic material, e.g., copper, that is formed using known techniques.

The semiconductor structure 300 further includes the power rails 120 (also known as metal lines). While referred to collectively, it will be appreciated that different instances of the power rails 120 (i.e., the power rails 120A, the power rails 120B) may have differing power supplies, much like those described in FIG. 1. The power rails 120 provide electricity to the vias 118. The power rails 120 may be formed of copper or other metals using known deposition techniques.

While the source/drain regions 112 and the source/drain regions 114 are illustrated with a particular alignment (misalignment/overlap/underlap/offset) with respect to the contacts 116, the vias 118, and the power rails 120, the sizing of the components and the layout, including a degree of alignment, may be varied in other embodiments. However, as illustrated, instances of the source/drain regions 112, the source/drain regions 114, the contacts 116, the vias 118, and the power rails 120 are at least partially in vertical alignment such that they are conductively connected. Even in embodiments having a misalignment (or underlap/offset) of the source/drain regions 112 or the source/drain regions 114 with the power rails 120, for example, the contacts 116 may be formed wide enough to bridge the gap created by the offset (not shown).

Importantly, FIG. 3-4 illustrate how the power rails 120 align with the source/drain regions 112 and the source/drain regions 114 in cross section A as well as the source/drain regions 112 and the source/drain regions 114 in cross section B. For example, the power rail 120 in cross section A aligns with two source/drain regions 112A and the source/drain regions 114A while simultaneously aligning with a source/drain regions 112B or the source/drain regions 114B in cross section B. Thus, the continuous mixed row of the cells 102A and the cells 102B maintain dual alignment with the power rails 120.

It should be noted that FIG. 3 omits illustration of the vias 118 and contacts 116 for purposes of clarity. FIG. 4, however, illustrates how the vias 118 and contacts 116 provide electrical conductivity to the source/drain regions 112 and the source/drain regions 114. In addition, although not shown, the semiconductor structure 100 may additionally include other components, e.g., a gate that, when powered/unpowered, enables connectivity between the source/drain regions 112 and the source/drain regions 114 through one or more channels (additionally not shown).

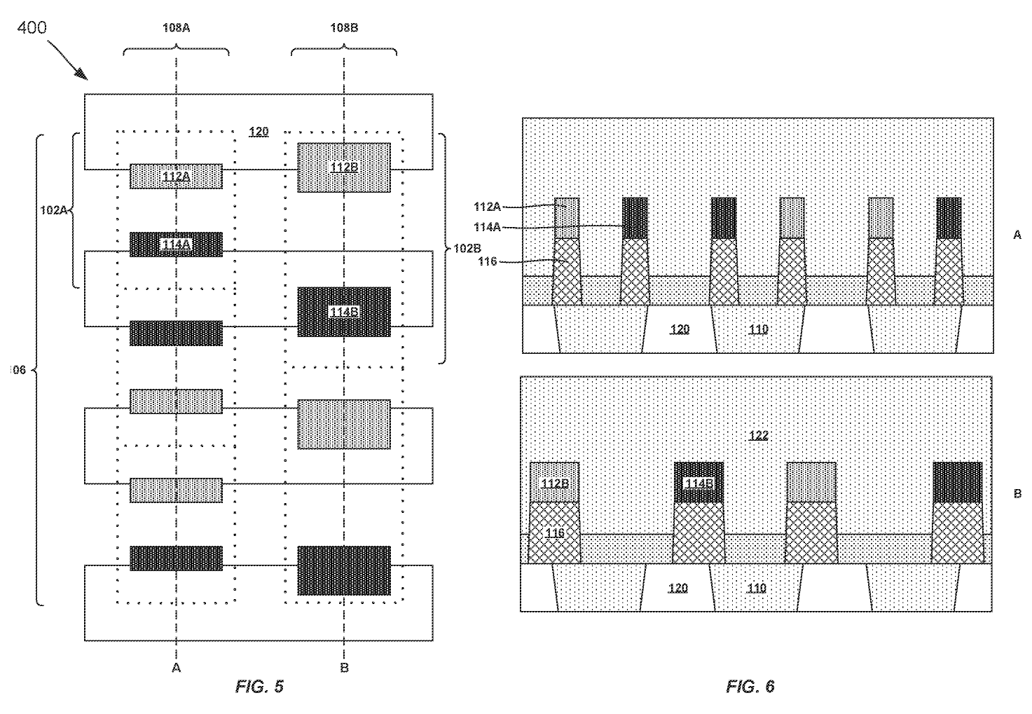

FIG. 5 illustrates a top view of a semiconductor structure 400 while FIG. 6 illustrates cross-sectional views taken along dashed line A and dashed line B of FIG. 5, according to an embodiment.

The semiconductor structure 400 illustrates a semiconductor device implementing a backside power rail.

In embodiments, the semiconductor structure 400 illustrated by FIG. 5 is similar to the semiconductor structure 300 with the exception of the power rails 120 being positioned on a backside of the device. Restated, the power rails 120 are positioned on an opposite side of the substrate 110 than the active device side.

Accordingly, the semiconductor structure 400 illustrated by FIG. 5 is similar in terms of components to the semiconductor structure 300. For example, the semiconductor structure 400 similarly includes a substrate 110, source/drain regions 112, source/drain regions 114, contacts 116, power rails 120, and dielectric region 122. All of such components may be composed of similar materials and made using similar techniques to those described with respect to the semiconductor structure 300.

Dissimilar to the semiconductor structure 300, however, the semiconductor structure 400, in this embodiment, does not require vias to transfer power from the power rails 120 to the contacts 116. Instead, as illustrated, the contacts 116 are formed in contact with the power rails 120.

In the embodiment shown by the semiconductor structure 400, the power rails 120 may be formed, for example, after flipping a wafer on which the semiconductor structure 400 is formed, providing access to an underside of the substrate.

Importantly, however, the power rails 120 maintain proper alignment with both the cells 102A and the cells 102B, namely the source/drain regions 112 and the source/drain regions 114 thereof. Thus, whether the power rails 120 are on a frontside or a backside of the semiconductor device, the benefits of implementing a 1:1.5 cell 102A to cell 102B ratio remain the same.

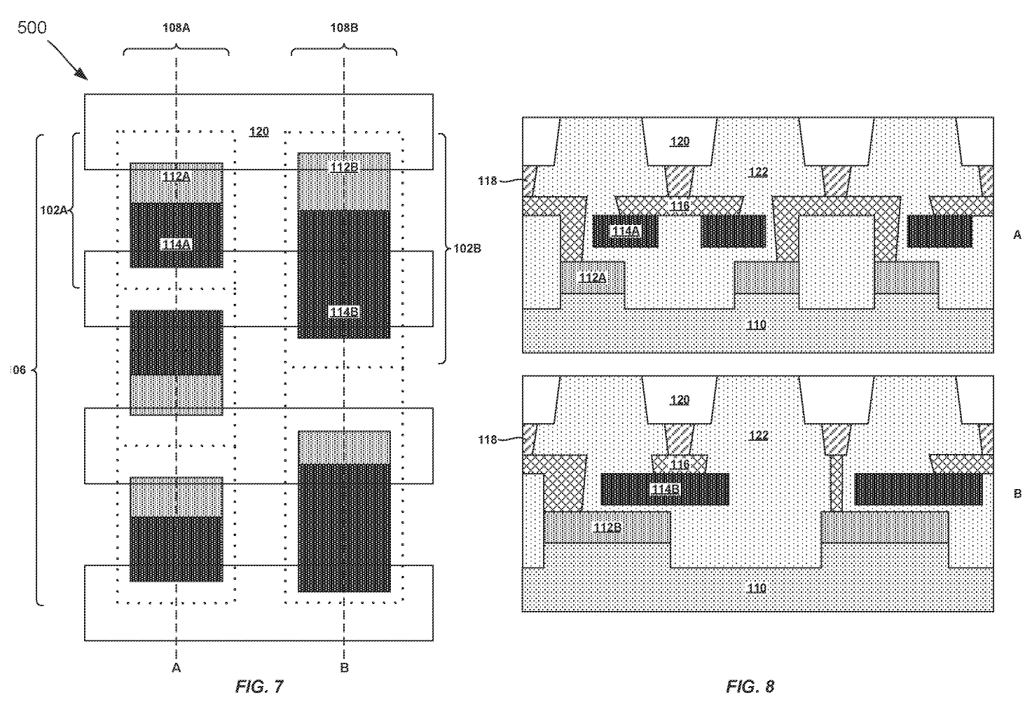

FIG. 7 illustrates a top view of a semiconductor structure 500 while FIG. 8 illustrates cross-sectional views taken along dashed line A and dashed line B of FIG. 7, according to an embodiment.

The semiconductor structure 500 illustrates a stacked semiconductor device having a frontside power rail.

In embodiments, the semiconductor structure 500 illustrated by FIG. 7 is similar to the semiconductor structure 300 in that it implements a frontside power rail. By contrast, however, the semiconductor structure 500 instead illustrates the use of stacked transistors. Restated, and in contrast to a single layer of devices as depicted by the semiconductor structure 300, the semiconductor structure 500 illustrates stacked layers of devices.

Nonetheless, the components illustrated by the semiconductor structure 500 may be composed of similar materials and made using similar techniques to those described previously. The key advantage provided by the configuration of the semiconductor structure 500 is the ability to further vary the sizing and positioning of the source/drain regions 112, the source/drain regions 114, and the contacts 116. Again, however, the power rails 120 maintain proper alignment with both the cells 102A and the cells 102B, namely the source/drain regions 112 and the source/drain regions 114 thereof. Thus, whether implementing a single layer of devices or stacked layers of devices, the benefits of implementing a 1:1.5 cell 102A to cell 102B ratio remain the same.

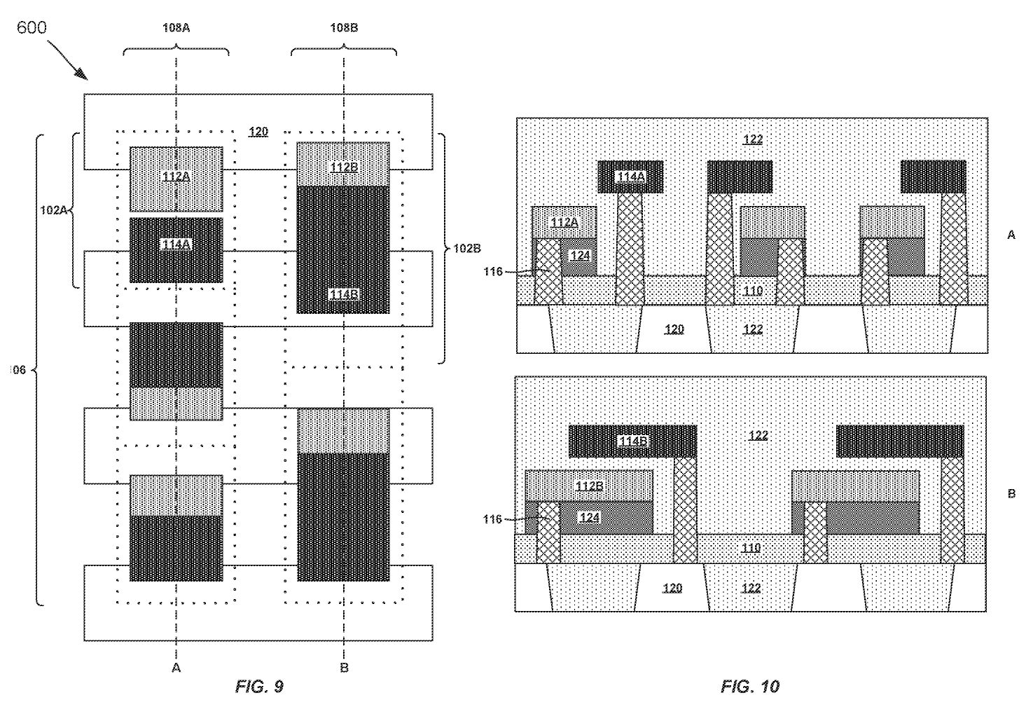

FIG. 9 illustrates a top view of a semiconductor structure 600 while FIG. 10 illustrates cross-sectional views taken along dashed line A and dashed line B of FIG. 9, according to an embodiment.

The semiconductor structure 600 illustrates a stacked semiconductor device having a backside power rail.

In embodiments, the semiconductor structure 600 illustrated by FIG. 5 is similar to the semiconductor structure 400 in that it implements a backside power rail. By contrast, however, the semiconductor structure 600 instead illustrates the use of stacked transistors. Restated, and in contrast to a single layer of devices as depicted by the semiconductor structure 400, the semiconductor structure 600 illustrates stacked layers of devices.

The components illustrated by the semiconductor structure 600 may be composed of similar materials and made using similar techniques to those described previously. Again, however, the power rails 120 maintain proper alignment with both the cells 102A and the cells 102B, namely the source/drain regions 112 and the source/drain regions 114 thereof. Thus, even when implementing stacked layers of devices with a backside power rail, the benefits of implementing a 1:1.5 cell 102A to cell 102B ratio remain the same.

Advantages of the invention implementing a 1:1.5 cell 102A to cell 102B ratio include improved power, performance, and area due to multi cell height designs with cells of both heights appearing within a given column and/or row. In addition, the invention provides improved area utilization due to the height of the cells 102B being equal to 1.5x that of the cell 102A, rather than conventional multi-rows of cells 102 implementing 2x, 3x, etc. Further, continuity of back-end-of-line (BEOL) layers, such as power rails, for robustness of power grid and route-ability, are improved through use of a standardized power rail layout.

For example, the continuous mixed row configuration allows for the integration of cells with varying heights within a single design, potentially enabling more efficient use of chip area. This approach may provide designers with greater flexibility in accommodating diverse circuit components while maintaining a standardized, structured layout.

In some cases, the combination of continuous mixed rows and shared power rails may offer advantages in terms of wire length reduction, signal propagation, power integrity, signal integrity, and thermal management. These potential benefits may be particularly relevant as semiconductor devices continue to shrink and circuit densities increase.

Shared power rails, a key feature of this design methodology, may contribute to improved power distribution across the integrated circuit. By implementing a shared power rail structure, the design potentially reduces the complexity of power routing and may enhance overall power delivery efficiency.

The continuous mixed row standard cell design with shared power rails may be applicable to various transistor configurations. In some cases, the semiconductor structure may include a fin field-effect transistor (FinFET) configuration. This configuration may allow for improved performance and reduced power consumption in certain applications.

In some embodiments, the semiconductor structure may incorporate a gate-all-around (GAA) configuration in some implementations. The GAA configuration may provide enhanced control over the channel region, potentially leading to improved electrical characteristics and scalability.

The continuous mixed row configuration may allow for shorter interconnections between components. The strategic placement of cells with different heights may enable more direct routing paths for signals between adjacent cells. This reduction in wire length may potentially lead to improvements in signal propagation and reduced power consumption within the integrated circuit.

The shared power rail structure may provide flexibility in power distribution. The alternating pattern of power rails may allow for efficient power delivery to both N-type and P-type regions within the cells. This configuration may help maintain consistent power supply across different areas of the integrated circuit.

In some cases, the continuous mixed row design may enable more efficient placement of complex circuit functions. By combining cells of different heights in adjacent columns, designers may have greater flexibility in implementing various circuit functionalities within a compact area. This approach may allow for optimization of both area utilization and circuit performance.

The design may also facilitate improved routing between cells. The mixed height configuration may create opportunities for more direct paths between components in adjacent cells, potentially reducing the complexity of interconnect routing. This may contribute to reduced parasitic capacitance and improved signal integrity within the integrated circuit.

The shared power rail structure may help in managing power-related issues. By providing a consistent power distribution network across multiple cells, the design may help reduce voltage drops and improve overall power integrity within the integrated circuit. This may potentially lead to more stable operation and improved performance of the circuit.

In some implementations, the continuous mixed row design may allow for better thermal management. The arrangement of cells with different heights may create opportunities for more even heat distribution across the chip surface. This may help in reducing localized hot spots and potentially improve the overall thermal characteristics of the integrated circuit.

The design approach may also provide benefits in terms of scalability. The modular nature of the continuous mixed row configuration may allow for easier expansion or modification of the circuit design. Designers may be able to add or modify cells within the existing framework without significant disruption to the overall layout structure.

In some cases, the continuous mixed row design with shared power rails may contribute to improved manufacturability. The regular structure of the power rail network and the organized arrangement of cells may potentially simplify certain aspects of the manufacturing process, such as lithography and metal layer deposition.

The design may also offer advantages in terms of design reuse and modularity. The standardized approach to cell arrangement and power distribution may allow for easier integration of pre-designed functional blocks or intellectual property (IP) cores into new circuit designs. This may potentially reduce design time and improve overall design efficiency.

The continuous mixed row standard cell design with shared power rails may be applicable to various types of integrated circuits and semiconductor devices. In some implementations, this design approach may be particularly useful in applications where area efficiency and reduced wire length are important considerations.

A number of implementations have been described. Nevertheless, it will be understood that various modifications may be made without departing from the spirit and scope of the disclosure. Accordingly, other implementations are within the scope of the following claims.

1. A semiconductor structure, comprising:
a first standard cell column comprising three first N and P transistor pairs; and
a second standard cell column horizontally adjacent to the first standard cell column comprising two second N and P transistor pairs,
wherein a top edge and a bottom edge of the first standard cell column is horizontally aligned with a respective top edge and a respective bottom edge of the second standard cell column.

2. The semiconductor structure of claim 1, wherein each of the three first N and P transistor pairs and each of the two second N and P transistor pairs at least partially align with two or more power rails.

3. The semiconductor structure of claim 2, wherein an N portion of each of the three first N and P pairs and the two second N and P pairs at least partially aligns with a first power rail of the two or more power rails, and wherein a P portion of each of the three first N and P pairs and the two second N and P pairs at least partially aligns with a second power rail of the two or more power rails.

4. The semiconductor structure of claim 2, wherein a top edge and a bottom edge of each of the three first N and P pairs at least partially align with one of the two or more power rails, and wherein one of a top edge or a bottom edge of each of the two second N and P pairs at least partially aligns with one of the two or more power rails.

5. The semiconductor structure of claim 2, wherein one of a top edge or a bottom edge of each of the two second N and P pairs does not at least partially align with one of the two or more power rails.

6. The semiconductor structure of claim 2, wherein a non-edge of each of the two second N and P pairs at least partially aligns with one of the two or more power rails.

7. The semiconductor structure of claim 2, wherein the two or more power rails are implemented on a frontside of the semiconductor structure.

8. The semiconductor structure of claim 2, wherein the two or more power rails are implemented on a frontside of the semiconductor structure.

9. The semiconductor structure of claim 2, wherein the N and P transistor pairs are implemented as stacked transistors.

10. The semiconductor structure of claim 1, wherein the second N and P transistor pairs are one and one-half times a height dimension of the first N and P transistor pairs.

11. The semiconductor structure of claim 1, wherein the first standard cell column and the second standard cell column are a same height dimension.

12. The semiconductor structure of claim 2, wherein the two or more power rails are spaced apart vertically by vertical edges of the three first N and P transistor pairs.

13. The semiconductor structure of claim 1, wherein the first standard cell column and the second standard cell column comprise a standard cell group.

14. The semiconductor structure of claim 13, wherein the standard cell group is adjacently replicated.

15. A semiconductor structure comprising:
a continuous mixed row of N and P transistor pairs that include a first N and P transistor pair having a first height and a second N and P transistor pair having a second height, wherein the second height is one and one-half times a height of the first height.

16. The semiconductor structure of claim 15, wherein the continuous mixed row is aligned with a power rail on a top edge and a bottom edge of the continuous mixed row.

17. The semiconductor structure of claim 16, wherein the second N and P transistor pair is misaligned with at least one of the power rail on the top edge or the power rail on the bottom edge.

18. The semiconductor structure of claim 15, wherein the continuous mixed row is replicated to three vertically adjacent continuous mixed rows that contain three vertically stacked first N and P transistor pairs in a first column and two vertically stacked second N and P transistor pairs in a second column, and wherein the first column and the second column are a same height.

19. A semiconductor structure comprising:
A first standard cell column and a second standard cell column, wherein the first standard cell column and the second standard cell column have a same height, and wherein the first standard cell column includes three standard cells while the second standard cell column includes two standard cells.

20. The semiconductor structure of claim 19, wherein the three standard cells and the two standard cells each share alignment with two power rails.
